(19) United States
(12) Patent Application Publication
(10) Pub. No.: US 2012/0094457 A1
(43) Pub. Date: Apr. 19, 2012

(54) STI-ALIGNED LDMOS DRIFT IMPLANT TO ENHANCE MANUFACTURABILITY WHILE OPTIMIZING RDSON AND SAFE OPERATING AREA

(76) Inventor: Ann Gabrys, Santa Clara, CA (US)

(21) Appl. No.: 12/904,368

(22) Filed: Oct. 14, 2010

(51) Int. Cl. H01L 21/336; H01L 21/265

(52) U.S. Cl. 438/286; 438/524; 257/E21.334; 257/E21.409

(57) ABSTRACT

A method is provided that utilizes the shallow trench isolation (STI) process to incorporate a self-aligned drift implant into the extrinsic drain of a laterally diffused MOS (LDMOS) device. Since the location of the implant edge with respect to the edge of the STI is determined by the shallow trench etch, the edge location is extremely consistent and can significantly reduce the standard deviation of device parameters dependent upon the location of the implant. This, in turn, allows for a more compact device design with optimized performance.

### TECHNICAL FIELD

The present invention relates to semiconductor integrated circuit devices and, in particular, to utilization of a shallow trench isolation (STI) process to incorporate a self-aligned drift implant into the extrinsic drain of a laterally diffused MOS (LDMOS) transistor.

### BACKGROUND

A Lateral Diffusion Metal-Oxide-Semiconductor (LDMOS) transistor is a high-voltage device that is commonly utilized in numerous integrated circuit applications. LDMOS transistors are compatible with many high density integrated circuit process technologies. A primary design goal of an LDMOS device is to minimize “on” resistance while maintaining a high breakdown voltage and robust safe operating area (SOA) over the current and voltage operating space.

FIG. 1 shows an embodiment of a conventional N-type LDMOS (NLDMOS) transistor 100. In the NLDMOS transistor 100, an N-type epitaxial layer 102 is formed on an N-type buried layer 104. The epitaxial layer 102 has a dopant concentration that provides a desired drift region (Drift 1) for the NLDMOS device 100. A P-type well region (Body) 106 is formed in the epitaxial layer 102. The combination of the N-type buried layer 104 and the N-type epi region 102 isolates the P-type Body 106 from the substrate and sets the breakdown voltage between a drain region (D) 110 and the substrate. An N-type source region (S) 108 is formed in the P-type Body 106 and the N-type drain region (D) 110 is formed in the epitaxial layer 102. A polysilicon gate 112 and an underlying layer of gate oxide 114 are formed on the surface of the epitaxial layer 102 overlying the P-type channel region that is defined by the Body 106 between the source region 108 and the drain region 110. A lightly doped drain (LDD) implant region 109 is formed on the source/Body side of the polysilicon gate 112. Dielectric spacers 111, typically silicon oxide, are formed on the sidewalls of the gate 112. Thus, the polysilicon gate 112, the N-type source region 108 and the N-type drain region 110 define a lateral NMOS transistor. In order to withstand the high voltages applied to the drain region 110, shallow trench isolation (STI) 116, typically silicon dioxide, is formed between the gate 112 and the drain region 110 to increase the carrier drift/depletion region, and thus the breakdown voltage, as well as to decrease the gate/drain capacitance and gate charge figure of merit (which is important for large-signal switching applications).

As shown in FIG. 1, the drift region (Drift 1) either exists in, or is formed of, the epitaxial layer 102 of the NLDMOS device structure 100 between the source region 108 and the drain region 110. FIG. 1 also shows a secondary, heavier drift implant region (Drift 2) positioned beneath the STI 116. The secondary drift implant region (Drift 2) manipulates the internal electric fields such that impact ionization is drawn away from the gate oxide 114 and the STI 116 and instead is drawn into the bulk, thereby improving hot carrier reliability. The secondary drift implant region (Drift2) also improves Rdson and on-state breakdown characteristics by increasing the concentration in the majority of the drift region, thus reducing drain resistance. These device characteristics depend critically on the edge location of the secondary drift region (Drift2) dopant peak with respect to the edge of the STI 116.

Those skilled in the art will appreciate that a complementary PLDMOS device can be similarly designed by changing the N-type dopants in the FIG. 1 device structure to P-type and vice versa. The drift region implant purpose remains the same for the PLDMOS device.

### SUMMARY OF THE INVENTION

The present invention provides a method that utilizes a shallow trench isolation (STI) process to incorporate a self-aligned drift implant into the extrinsic drain of a laterally diffused MOS (LDMOS) device. Since the location of the implant edge with respect to the edge of the STI is determined by the shallow trench etch, the edge location is extremely consistent and can significantly reduce the standard deviation of LDMOS device parameters that are dependent upon the location of the implant. This, in turn, allows for a more compact device design with optimized performance.

An embodiment of the invention provides a method of forming an LDMOS transistor structure, the method comprising: forming a layer of hard mask material on an underlying layer of doped semiconductor material; patterning the hard mask layer to expose a region of the doped semiconductor material; etching the exposed region of the doped semiconductor material to define a trench in the doped semiconductor material; utilizing the patterned hard mask to introduce additional dopant into the trench defined in the doped semiconductor material; and performing steps to complete the LDMOS transistor structure to include the trench.

The features and advantages of the various aspects of the present invention will be more fully understood and appreciated upon consideration of the following detailed description and the accompanying drawings, which set forth illustrative embodiments.

### BRIEF DESCRIPTION OF THE DRAWINGS

FIG. 1 is a partial cross-section drawing illustrating an embodiment of a lateral diffusion MOS (LDMOS) transistor.

FIGS. 2A-2I are partial cross-section drawings illustrating an embodiment of a process flow for fabrication an LDMOS transistor in accordance with the concepts of the present invention.

FIGS. 3A and 3B are graphs illustrating device performance improvement and potential reduction in manufacturing variability of the self-aligned implant versus a mask-aligned implant edge.

### DESCRIPTION OF THE INVENTION

The following describes embodiments of a method of fabricating a lateral diffusion metal-oxide-semiconductor (LDMOS) transistor in which the dopant utilized to form the secondary drift implant region is introduced directly after the shallow trench isolation (STI) etch utilizing the STI hard mask. Introducing the dopant directly after the STI etch, utilizing the STI hard mask to self-align the implant to the STI, eliminates any misalignment issues and enables the device designer to take full advantage of the benefits of this solution. The self-aligned implant can be either a single implant or chain of two or more implants. For example, in some embodiments, a chain of two zero-degree implants can be utilized to improve Rdson and safe operating area (SOA) by reducing current crowding beneath the STI. In other embodiments, an angled implant of the same dopant type can be utilized in conjunction with a zero degree implant to independently optimize the dopant concentration along the sidewalls of the STI for hot carrier performance and breakdown voltage, utilizing the STI hard mask to shadow the dopant and keep it from the drain region directly beneath the STI; again, the zero-degree implant is optimized to engineer the dopant concentration in that portion of the drift region. An additional angled implant of the opposite dopant type can also be introduced to counter-dope the corners of the STI. Reducing the dopant concentration in this region reduces impact ionization (II) at that point and moves the II peak deeper into the bulk and away from the STI corner. The hard mask shadowing in this case prevents the introduction of the opposite dopant type into the bottom of the STI, thereby preventing a reduction in concentration that could lead to an increased resistance in an undesirable location.

While the embodiments described below are directed to NLDMOS devices, those skilled in the art will appreciate that the disclosed concepts are equally applicable to PLDMOS devices. Those skilled in the art will also appreciate that the disclosed concepts are applicable to alternative LDMOS architectures. For example, two alternative NLDMOS architectures can be defined: one that implements a P-type epi region and PBL with the N-type drift implants, effectively linking the device Body to the substrate, and another that uses a P-type epi region NBL, creating a five terminal device. While these architectures are generally considered to be less desirable, the self-aligned drift implant concepts disclosed herein may be used with these doping schemes for the same reasons set forth above.

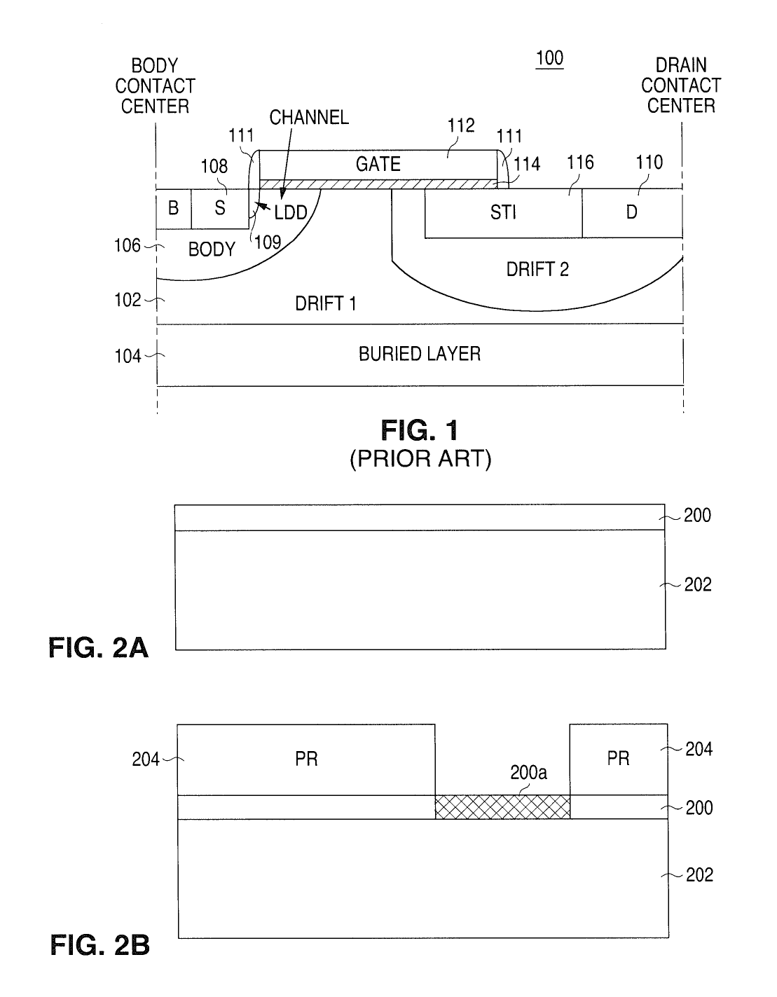

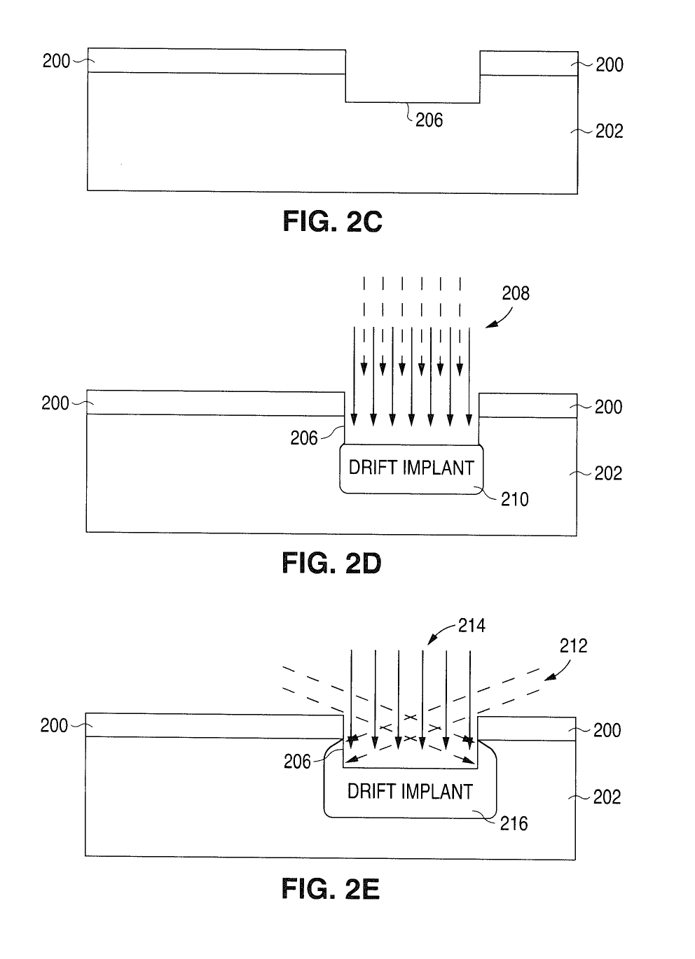

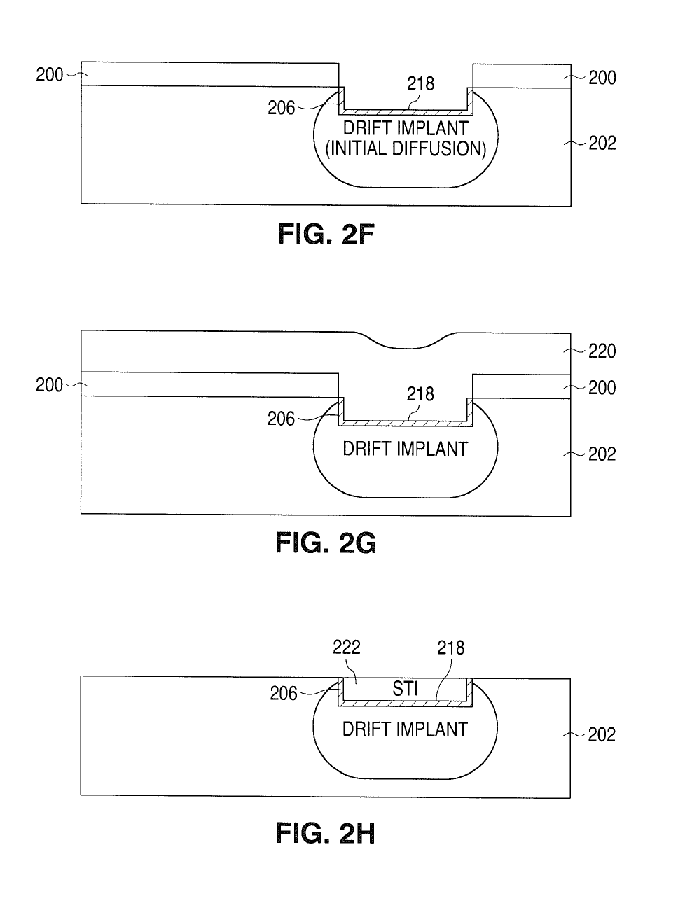

FIG. 2A shows a layer of hard mask material 200 formed on an underlying layer of n-doped semiconductor material 202, such as for example, the doped epitaxial silicon layer described above in conjunction with FIG. 1. While not so limited, the material of the hard mask 200 may be selected from the group consisting of oxide or nitride and/or combinations thereof. Those skilled in the art will appreciate that other hard mask materials, e.g., metal or polysilicon are also available for this application, but typically would not be used at this point in a process flow. As shown in FIG. 2B, after formation of the hard mask layer 200, a layer of photoresist (PR) 204 is deposited and patterned in accordance with conventional photolithographic techniques to expose a region 200a of the hard mask layer 200. The exposed region 200a of the hard mask layer 200 is then etched to expose the underlying layer of n-doped semiconductor material 202. The exposed n-doped semiconductor material 202 is then etched to define an STI trench 206 and the photoresist layer 204 is stripped, as shown in FIG. 2C.

N-type dopant is then introduced into the layer of n-doped semiconductor material 202 utilizing either a single implant or a chain of implants. The STI hard mask 200 is utilized to self-align the secondary drift implant to the STI trench 206. FIG. 2D shows an embodiment that utilizes a chain of two zero-degree implants 208 to form a secondary drift implant region 210 for an NLDMOS device that improves Rdson and SOA by reducing current crowding beneath the STI. FIG. 2E shows an embodiment that utilizes an angled implant 212 in conjunction with a zero-degree implant 214 to form a secondary drift implant region 216 such that the dopant concentrations along the sidewalls of the STI trench are independently optimized for hot carrier performance and breakdown voltage using the hard mask 200 to shadow the dopant and keep it from the drain region directly beneath the STI; as in the FIG. 2D embodiment, the zero degree implant is optimized to engineer the dopant concentration in that portion of the drift region 216. Those skilled in the art will appreciate that the implant parameters, such as, for example, dopant species, dopant dosage, implant energy and angled implant degree of tilt, will depend upon a particular LDMOS device application.

Referring to FIG. 2F, following the drift implant, a thin (e.g., a few hundred angstroms) layer of STI liner oxide 218 is thermally grown on exposed surfaces of the STI trench 206, resulting in an initial diffusion of the secondary drift implant region. A layer of STI trench fill dielectric material 220, for example chemical vapor deposited (CVD) silicon dioxide, is then formed over the FIG. 2F structure to fill the oxide lined STI trench 206, as shown in FIG. 2G. A planarization step, for example chemical mechanical polishing (CMP), is then performed to remove unwanted trench fill dielectric material 220. The patterned hard mask 200 is then etched away, resulting in the STI structure 222 shown in FIG. 2H.

Referring to FIG. 2I, the steps of the process flow then continue in a manner well know to those skilled in the art to complete the LDMOS structure. As shown in the FIG. 2I embodiment, a p-type well region (Body) 224 is formed in the n-doped semiconductor material 202 on a first side of and spaced apart from the STI 222. A layer of gate dielectric material, e.g., silicon oxide, and an overlying layer of polysilicon are then formed and patterned to define a polysilicon gate 230 and underlying gate oxide 232 overlying a P-type channel region that is defined by the Body 224. Alternatively, a P-type Body implant can be self-aligned to the device gate by introducing it after the formation of the polysilicon gate 230 and gate oxide 232. A lightly dope drain (LDD) region 234 is then introduced on the source/Body side of the polysilicon gate 230, followed by the formation of dielectric (e.g., silicon oxide) gate sidewall spacers 236. An N-type source region 226 is formed in the p-well 224 and an N-type drain region 228 is formed in the n-doped semiconductor material 202 on a second side of and adjacent to the STI 222. The P-type Body 224 overlayed by the polysilicon gate 230 and gate oxide 232 forms a P-type channel region between the N-type source region 226 and the N-type drain region 228. Thus, the poly gate 230, the N-type source region 226 and the N-type drain region 228 define an LDMOS device. It is reiterated that the concepts of the invention are not limited to the NLDMOS architecture shown in the FIG. 2I embodiment, but are applicable to various well known NLDMOS and PLDMOS device architectures.

The final secondary drift implant (Drift2) as shown in FIG. 2I results from the subsequent STI liner oxidation, well rapid thermal anneal (RTA), gate oxidation and LDD/emitter RTA thermal steps in the process flow. The angled sidewall implants diffuse laterally out from the STI 222 and vertically towards the surface and the STI corner. The concentration at the STI corner is reduced by shadowing the sidewall implants with the STI hard mask. The zero-degree implant diffuses down from the bottom of the STI 222 and laterally beyond the STI corners to provide a low-resistance conduction path. Increasing the energy of the zero-degree and angled implants will push the concentration peak away from the Si/STI interface and the surface under the gate oxide.

Additional deep drift implants, aligned using a surface mask, can be used in conjunction with the self-aligned drift implant in the extrinsic and/or intrinsic drain regions to further reduce the drain resistance and optimize the on-state breakdown characteristics.

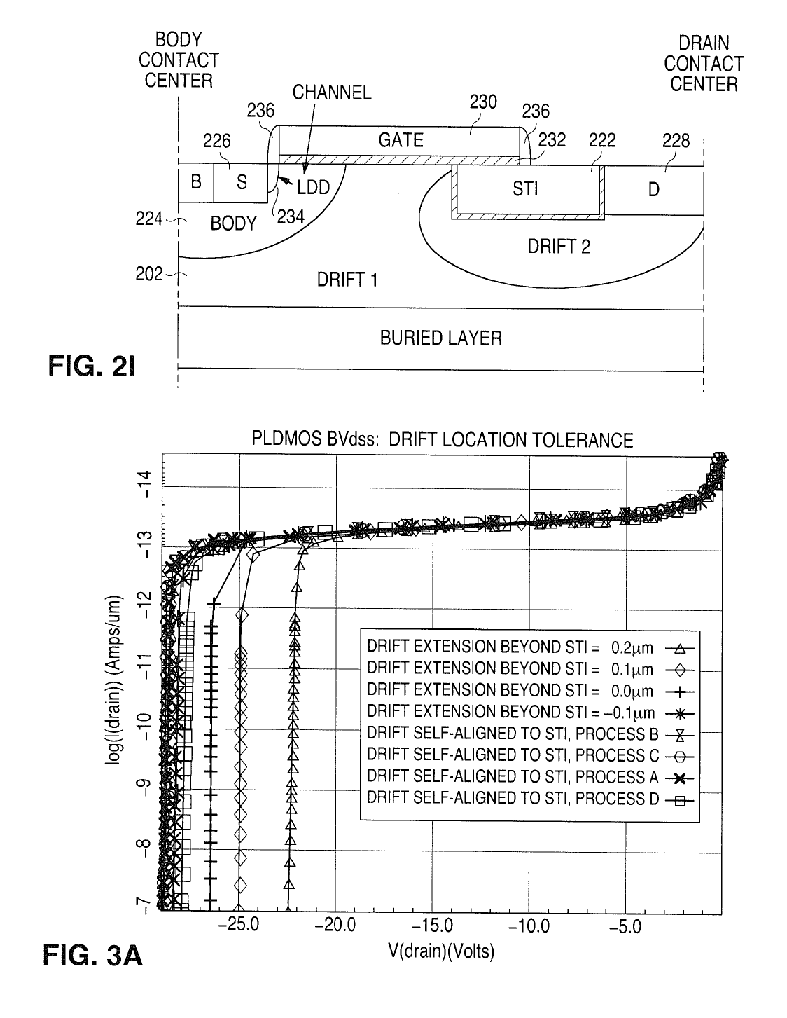

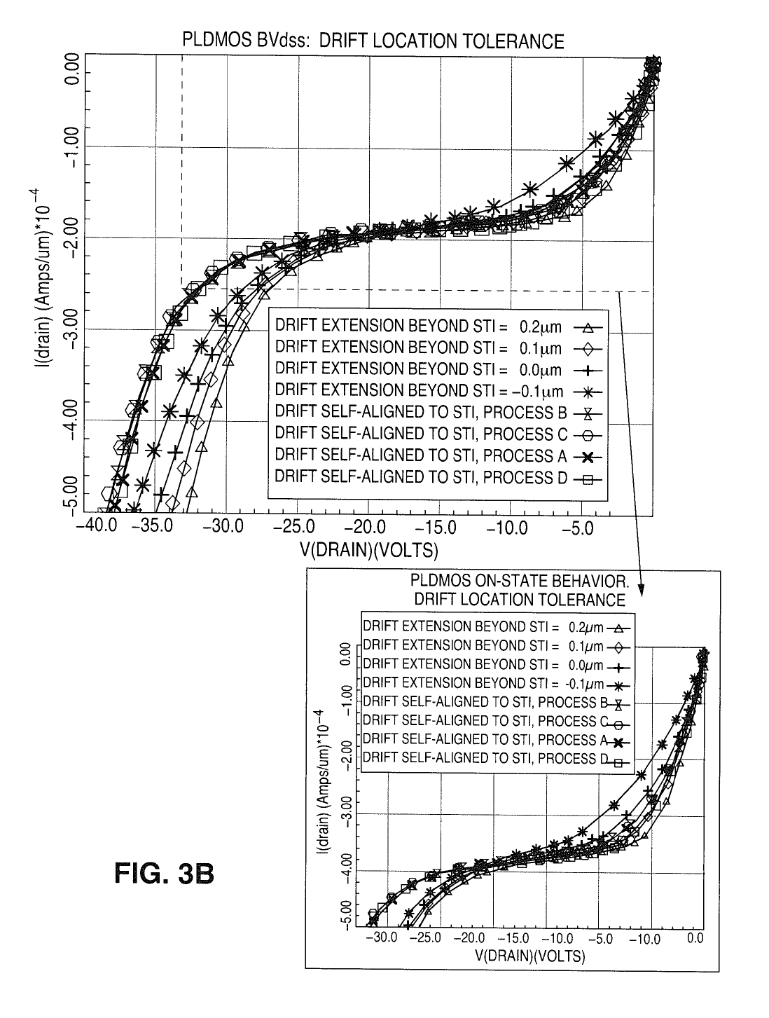

FIGS. 3A and 3B illustrate the device performance improvement and potential reduction in manufacturing variability of the self-aligned implant disclosed herein versus the conventional mask-aligned implant edge. Process misalignment is typically on the order of 0.1 to 0.2 μm, and edge shifts of this magnitude yield significant variation in device performance parameters such as the onset of impact ionization (on-state breakdown and SOA) and on-resistance. In FIGS. 3A and 3B, self-aligned Processes A, B and C differ by the energy of the self-aligned implant where

E_{B}=E_{A}+20%

E_{C}=E_{A}+40%

Self-aligned Process D adds angled implants to Process B.

Within the mask-aligned implant group, BVdss varies significantly over the range presented. For misalignment of 0.1 μm, the value in this example varies by approximately 2V, or nearly 10%, and by nearly 6V over the entire alignment range specified. Within the self-aligned implant group, BVdss shifts by only roughly 1V over the entire range of implant conditions specified.

The slope of the on-state Id-Vds curve near the Rdson condition (Vds=0.1V) shows a relative decrease of approximately 20% from the 0.1 μm to the −0.1 μm Drift Extension Beyond STI condition. The self-aligned group decreases by approximately 8% from the best process condition (Process D) to worst condition (Process C), which is a significant improvement in an important operational figure of merit.

As can be seen in FIG. 3B, the linear portion of the Id-Vds curve was also improved by using the self-aligned Drift2 implant over the mask-aligned Drift2. The onset of avalanche multiplication was pushed to higher voltages and the voltage at which onset occurs was stabilized.

It should be understood that the particular embodiments of the subject matter disclosed above have been provided by way of example and that other modifications may occur to those skilled in the art without departing from the scope of the claimed subject matter as expressed in the appended claims and their equivalents.

1. A method of forming an LDMOS transistor structure, the method comprising:
forming a layer of hard mask material on an underlying layer of doped semiconductor material;
patterning the hard mask layer to expose a surface region of the layer of doped semiconductor material;
etching the exposed surface region of the layer of doped semiconductor material to define a trench in the doped semiconductor material;
utilizing the patterned hard mask to introduce additional dopant into the doped semiconductor material defining the trench;
filling the entire trench with dielectric material; and
performing steps to complete the LDMOS transistor structure to include the dielectric material filling the trench.

2. The method of claim 1, wherein the step of utilizing the patterned hard mask to introduce additional dopant comprises utilizing a zero-degree implant to introduce additional dopant.

3. The method of claim 1, wherein the step of utilizing the patterned hard mask to introduce additional dopant comprises utilizing an angled implant to introduce additional dopant.

4. The method of claim 1, wherein the step of utilizing the patterned hard mask to introduce additional dopant comprises two or more implants of additional dopant.

5. The method of claim 4, wherein the two or more implants include at least one zero-degree implant.

6. The method of claim 4, wherein the two or more implants include at least one angled implant.

7. The method of claim 4, wherein the two or more implants include at least one zero-degree implant and at least one angled-implant.

8. A method of forming an LDMOS transistor, the method comprising:
forming a layer of hard mask material on an underlying layer of semiconductor material having a first conductivity type;
patterning the layer of hard mask material to expose a surface region of the layer of semiconductor material;
utilizing the patterned layer of hard mask material to etch the exposed surface region of the layer of semiconductor material to define a trench in the layer of semiconductor material;
utilizing the patterned layer of hard mask material to introduce additional dopant having the first conductivity type into the semiconductor material defining the trench;
filling the entire trench with trench dielectric material;
removing the patterned layer of hard mask material;
forming a body region in the layer of semiconductor material, the body region having a second conductivity type that is opposite the first conductivity type, the body region being formed on a first side of and spaced apart from the filled trench;
forming a conductive gate over a channel region that is defined by the body region, the conductive gate being separated from the body region by intervening dielectric material;
forming a lightly doped drain (LDD) region on a source/body side of the conductive gate;
forming dielectric spacers on sidewalls of the conductive gate;
forming a source region having the first conductivity type in the body region; and
forming a drain region having the first conductivity type in the layer of semiconductor material, the drain region being formed on a second side of and adjacent to the filled trench.

9. The method of claim 8, wherein the hard mask material comprises silicon oxide.

10. The method of claim 8, wherein the hard mask material comprises silicon nitride.

11. The method of claim 8, wherein the hard mask material comprises a combination of silicon oxide and silicon nitride.

12. The method of claim 8, wherein the trench dielectric material comprises silicon dioxide.

13. The method of claim 8, wherein the conductive gate comprises polysilicon and the gate dielectric material comprises silicon oxide.

14. The method of claim 8, wherein the first conductivity type is N-type and the second conductivity type is P-type.

15. The method of claim 8, wherein the first conductivity type is P-type and the second conductivity type is N-type.

16. A method of forming an LDMOS transistor structure, the method comprising:
forming a layer of hard mask material on an underlying layer of doped semiconductor material;
patterning the layer of hard mask material to expose a surface region of the layer of doped semiconductor material;
etching the exposed region of the doped semiconductor material to define a trench having exposed surfaces in the doped semiconductor material;
utilizing the patterned hard mask to introduce additional dopant into the exposed surfaces in the doped semiconductor material;
filling the entire trench with trench dielectric material; and
performing steps to complete the LDMOS transistor structure to include the trench dielectric material, said steps including at least one thermal step such that the additional dopant introduced into the exposed surfaces in the doped semiconductor material diffuses in the doped semiconductor material.

17. The method of claim 16, wherein the doped semiconductor material comprises doped silicon and the at least one thermal step comprises growing thermal silicon oxide on the exposed surface in the doped silicon.

18. The method of claim 16, wherein the doped semiconductor material has a first conductivity type and the step of performing steps to complete the LDMOS transistor structure comprises:
filling the entire trench with trench dielectric material;
removing the patterned layer of hard mask material;
forming a body region in the layer of doped semiconductor material, the body region having a second conductivity type that is opposite the first conductivity type, the body region being formed on a first side and space apart from the filled trench;
forming a conductive gate over a channel region that is defined by the body region, the conductive gate being separated from the body region by intervening dielectric material;
forming a lightly doped drain (LDD) region on a source/body side of the conductive gate;
forming dielectric spacers on sidewalls of the conductive gate;
forming a source region having the first conductivity type in the body region; and
forming a drain region having the first conductivity type in the layer of doped semiconductor material, the drain region being formed on a second side of and adjacent to the filled trench.

19. The method of claim 16, wherein the step of utilizing the patterned hard mask to introduce additional dopant into the exposed surfaces of the doped semiconductor material comprises utilizing at least one zero-degree implant to introduce additional dopant.

20. The method of claim 19, wherein the step of utilizing the patterned hard mask to introduce additional dopant into the exposed surfaces of the doped semiconductor material comprises utilizing at least one angled implant to introduce additional dopant.
